(19) United States
(12) Patent Application Publication
(10) Pub. No.: US 2026/0314380 A1
(43) Pub. Date: Oct. 8, 2026

(54) UNIQUE VIA STRUCTURES FOR SEMICONDUCTOR PACKAGES

(71) Applicant: Micron Technology, Inc., Boise, ID (US)

(72) Inventors: Seng Kim Ye, Singapore (SG); Hong Wan Ng, Singapore (SG); Kelvin Aik Boo Tan, Singapore (SG); Chin Hui Chong, Singapore (SG); See Hiong Leow, Singapore (SG); Ling Pan, Singapore (SG)

(21) Appl. No.: 19/638,989

(22) Filed: Apr. 3, 2026

Related U.S. Application Data
(60) Provisional application No. 63/783,508, filed on Apr. 4, 2025.

(51) Int. Cl. H10W 20/43; H10W 20/00; H10W 20/42; H10W 20/44

(52) U.S. Cl. CPC H10W 20/43; H10W 20/077; H10W 20/42; H10W 20/4421

(57) ABSTRACT

Methods, systems, and devices for unique via structures for semiconductor packages are described. The described techniques provide for channel traces to be isolated from one another by forming openings that leverage existing via structures. For example, a stack of materials may include one or more vias that extend through the stack to support memory operations. A first surface of a via may couple with channel traces at a first layer of the stack of materials, where an opening may be formed such that a first channel trace remains electrically connected with the via and a second channel trace is electrically isolated from the first channel trace and the via. For example, one or more layers of material may be removed within a surface of the via and a resistive material may be added above the via, which may result in isolation of the second channel trace.

### CROSS REFERENCE

The present Application for Patent claims priority to U.S. Patent Application No. 63/783,508 by Ye et al., entitled “UNIQUE VIA STRUCTURES FOR SEMICONDUCTOR PACKAGES,” filed April 4, 2025, which is assigned to the assignee hereof, and which is expressly incorporated by reference in its entirety herein.

### TECHNICAL FIELD

The following relates to one or more systems for memory, including unique via structures for semiconductor packages.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports unique via structures for semiconductor packages in accordance with examples as disclosed herein.

FIGS. 2A and 2B show examples of a semiconductor device that supports unique via structures for semiconductor packages in accordance with examples as disclosed herein.

FIGS. 3A and 3B show examples of a semiconductor device that supports unique via structures for semiconductor packages in accordance with examples as disclosed herein.

FIG. 4 shows a flowchart illustrating a method or methods that support unique via structures for semiconductor packages in accordance with examples as disclosed herein.

### DETAILED DESCRIPTION

Semiconductor devices may be provided in accordance with various configurations, such as a 3-dimensional (3D) memory architecture. For example, a semiconductor package may include a stack of materials, where memory features (e.g., memory cells, access circuitry, controllers, and the like) may be formed within (or near) the stack of materials. In some examples, dimensions of a semiconductor package may be subject to one or more constraints, for example to support the semiconductor package being incorporated into other devices or systems. As an example, a height of a semiconductor package may be limited (e.g., to a dimension less than or equal to 0.7mm) based on dimensional constraints of the system into which it is being incorporated. To reduce a package height and adhere to the dimensional constraints, components of a semiconductor package may be distributed within a footprint of the semiconductor package. As described herein, the footprint of the semiconductor package may refer to a horizontal area of the semiconductor package, where components may be located (e.g., formed, placed, manufactured) above a substrate on which the semiconductor package is formed.

In some examples, components of a semiconductor package may be electrically connected by channel traces (e.g., conductive lines formed within the semiconductor package). For example, bond fingers (e.g., channel traces extending between components of the semiconductor package) may couple with and be configured to communicate signaling to one or more components of the semiconductor package. In some cases, when components are distributed within the footprint of the semiconductor package, the bond fingers may be located at or near an edge of the semiconductor package. When coupling the bond fingers with other components, a portion of the semiconductor package may be removed (e.g., one or more layers of materials may be etched, exhumed, or otherwise removed) to form a void or opening within the semiconductor package (e.g., an etchback opening (EBO)), which may support isolating connections (e.g., isolating signaling) between conductive lines. However, an EBO may be relatively large and may otherwise increase a size of the footprint of the semiconductor package (e.g., due to performing a plate line removal at or near the edge of the semiconductor package), which may result in the semiconductor package having one or more dimensions that are incompatible with some systems (e.g., the resulting semiconductor package may be undesirably large).

Techniques described herein provide for connections (e.g., conductive line connections, signal line connections) to be isolated from one another by forming EBOs that leverage existing via structures. For example, a stack of materials may include one or more vias that extend through the stack and couple with one or more memory features (e.g., coupling with memory cells, access circuitry, or both). In some cases, a first surface (e.g., a top surface) of a via may couple with channel traces at a first layer of the stack of materials. At the first layer, an EBO may be formed such that a first channel trace remains electrically connected with the via and a second channel trace is electrically isolated from the first channel trace and the via. For example, one or more layers of material may be removed within a surface of the via and a resistive material may be added (e.g., deposited) above the via, which may result in isolation of the second channel trace (e.g., to support the second channel trace being operable to communicate signaling to other components without interference from the first channel trace). In some cases, by utilizing existing via areas to isolate channel traces, a semiconductor package may adhere to dimensional constraints (e.g., a height constraint) while maintaining or reducing a footprint size of the semiconductor package, among other advantages.

In addition to applicability in memory systems as described herein, techniques for unique via structures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling semiconductor devices to be incorporated in other systems, which may improve user experience, among other benefits.

Features of the disclosure are illustrated and described in the context of systems, devices, and circuits. Features of the disclosure are further illustrated and described in the context of semiconductor devices and flowcharts.

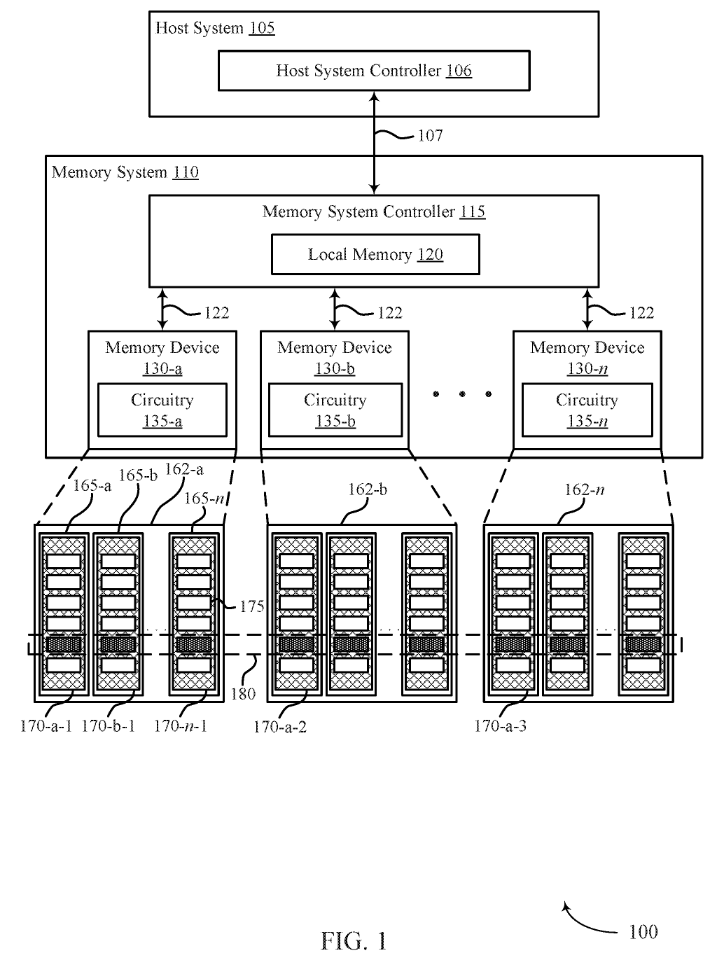

FIG. 1 shows an example of a system 100 that supports unique via structures for semiconductor packages in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface 107 with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via an interface 107. The host system 105 and the memory system 110 may, in some cases, be configured to communicate via the interface 107 using an associated protocol (e.g., to exchange or otherwise communicate control, address, data, and other signals between the memory system 110 and the host system 105). Examples of the interface 107 may include, but are not limited to, a SATA interface, a UFS interface, an eMMC interface, a PCIe interface, a USB interface, a Fiber Channel interface, a SCSI, a Serial Attached SCSI (SAS) interface, a Double Data Rate (DDR) interface, a DIMM interface (e.g., DIMM socket interface that supports DDR), an Open NAND Flash Interface (ONFI), Mobile Industry Processor Interface (MIPI) Unified Protocol (UniPro), MIPI Physical (M-PHY) interface, and a Low Power Double Data Rate (LPDDR) interface. In some examples, multiple such interfaces 107 may be included in or otherwise supported between a host system controller 106 of the host system 105 and a memory system controller 115 of the memory system 110 (e.g., the interface 107 may support communication via multiple protocol layers such as UFS at an application layer, UniPro at a transport layer, and M-PHY at a physical layer).

The memory system 110 may include a memory system controller 115 and one or more memory devices 130. A memory device 130 may include one or more memory arrays of any type of memory cells (e.g., non-volatile memory cells, volatile memory cells, or any combination thereof). The memory system 110 may include memory devices 130-a, 130-b, up to 130-n, where n represents any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the interface 107) and may be an example of a controller or control component configured to cause the memory system 110 to perform various operations in accordance with examples as described herein. The memory system controller 115 may also be coupled with and communicate with memory devices 130 via respective interfaces 122 to perform operations such as reading data, writing data, erasing data, or refreshing data at a memory device 130—among other such operations—which may generically be referred to as access operations. In some examples, the respective interfaces 122 may be examples of single data rate (SDR) interfaces, DRR interfaces, ONFI interfaces, and the like. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include volatile memory (e.g., static random access memory (SRAM), dynamic random access memory (DRAM), or other memory) that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as DRAM memory cells or SRAM memory cells.

In some examples, a memory device 130 may include (e.g., on the same die, within the same package) circuitry 135, which may execute or otherwise support operations on one or more memory cells of the respective memory device 130. Respective circuitry 135 may operate in conjunction with a memory system controller 115 or may perform one or more functions ascribed herein to the memory system controller 115. For example, as illustrated in FIG. 1, a memory device 130-a may include circuitry 135-a, a memory device 130-b may include circuitry 135-b, and a memory device 130-n may include circuitry 135-n.

In some cases, a memory device 130 may be or include a NAND device (e.g., NAND flash device). A memory device 130 may be or include a die 162 (e.g., a memory die). For example, in some cases, a memory device 130 may be a package that includes one or more dies 162. A die 162 may, in some examples, be a piece of electronics-grade semiconductor cut from a wafer (e.g., a silicon die cut from a silicon wafer). The memory cells for each die 162 may be arranged in one or more planes 165, and each plane 165 may include one or more blocks 170, where each block 170 may include one or more pages 175, and each page 175 may include a set of memory cells. In some examples, each die 162 may include n planes 165 and each plane may include m blocks 170, where n and m represent positive integers.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, concurrent operations may be performed on different planes 165 or on different blocks 170. For example, concurrent operations may be performed on memory cells within different blocks 170 so long as the different blocks 170 are in different planes 165. In some examples, each memory die 162 may include any quantity of planes 165. For example, the memory die 162-a may include a plane 165-a, a plane 165-b, and a plane 165-n, where n represents an Nth plane. The memory die 162-b and the memory die 162-n may also include N planes. In some cases, an individual block 170 may be referred to as a physical block, and a virtual block 180 may refer to a group of physical blocks 170 within which concurrent operations may occur. A virtual block 180 may be a logical structure that includes a plurality of blocks, where different blocks of the plurality of blocks may come from different planes 165 or different memory dies 162. In some cases, a virtual block may include blocks 170 from different memory devices 130 (e.g., including blocks in one or more planes 165 of memory device 130-a, memory device 130-b, and memory device 130-n). In some examples, a virtual block may include a respective block from each plane 165 (e.g., a block 170 from each plane 165) of one or more memory dies 162.

In some cases, the blocks 170 within a virtual block may have the same block address within their respective planes 165. For example, block 170-a-1 may be “block 0” of a first plane of die 162-a, block 170-a-2 may be “block 0” of a first plane of die 162-b, block 170-a-3 may be “block 0” of a first plane of die 162-n, and so on. By way of further example, block 170-b-1 may be “block 1” of a first plane of die 162-a and block 170-n1 may be “block n” of die 162-a, where n represents an Nth block. The memory die 162-b and the memory die 162-n may also include N blocks. In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). For example, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be restricted from being re-written with new data until they are erased. Thus, for example, an invalid page 175 may, in some cases, not be updated until the entire block 170 that includes the page 175 has been erased.

In some cases, a semiconductor package (e.g., a memory system 110) may be configured in accordance with a 3D memory architecture. For example, a memory system 110 may include a stack of materials, where memory features (e.g., memory devices 130, a memory system controller 115, or the like) may be formed within (or near) the stack of materials. In some examples, dimensions of a semiconductor package may be subject to one or more constraints, for example to support the semiconductor package being incorporated into other systems (e.g., a system 100). As an example, a height of a semiconductor package may be limited (e.g., to a dimension less than or equal to 0.7mm) based on dimensional constraints of the system into which it is being incorporated. To reduce a package height and adhere to the dimensional constraints, components of a semiconductor package may be distributed within a footprint (e.g., a top-down view) of the semiconductor package. As described herein, the footprint of the semiconductor package may refer to a horizontal area of the semiconductor package, where components may be located (e.g., formed, placed, manufactured) above a substrate on which the semiconductor package is formed.

In some examples, components of a semiconductor package may be electrically connected by channel traces (e.g., conductive lines formed within the semiconductor package). For example, bond fingers (e.g., channel traces extending between components of the semiconductor package) may couple with and be configured to communicate signaling to one or more components of the semiconductor package. In some cases, when components are distributed within the footprint of the semiconductor package, the bond fingers may be located at or near an edge of the semiconductor package. When coupling the bond fingers with other components, a portion of the semiconductor package may be removed (e.g., one or more layers of materials may be etched, exhumed, or otherwise removed) to form a void or opening within the semiconductor package (e.g., an etchback opening (EBO)), which may support isolating connections (e.g., isolating signaling) between conductive lines. However, an EBO may be relatively large and may otherwise increase a size of the footprint of the semiconductor package (e.g., due to performing a plate line removal at or near the edge of the semiconductor package), which may result in the semiconductor package having one or more dimensions that are incompatible with some systems (e.g., the resulting semiconductor package may be undesirably large).

Techniques described herein provide for connections (e.g., conductive line connections, signal line connections) to be isolated from one another by forming EBOs that leverage existing via structures. For example, a stack of materials may include one or more vias that extend through the stack and coupled with one or more memory features (e.g., coupling with memory cells, access circuitry, or both). In some cases, a first surface (e.g., a top surface) of a via may couple with channel traces at a first layer of the stack of materials. At the first layer, an EBO may be formed such that a first channel trace remains electrically connected with the via and a second channel trace is electrically isolated from the first channel trace and the via. For example, one or more layers of material may be removed within a surface of the via and a resistive material may be added (e.g., deposited) above the via, which may result in isolation of the second channel trace (e.g., to support the second channel trace being operable to communicate signaling to other components without interference from the first channel trace). In some cases, by utilizing existing via areas to isolate channel traces, a semiconductor package may adhere to dimensional constraints (e.g., a height constraint) while maintaining or reducing a footprint size of the semiconductor package, among other advantages.

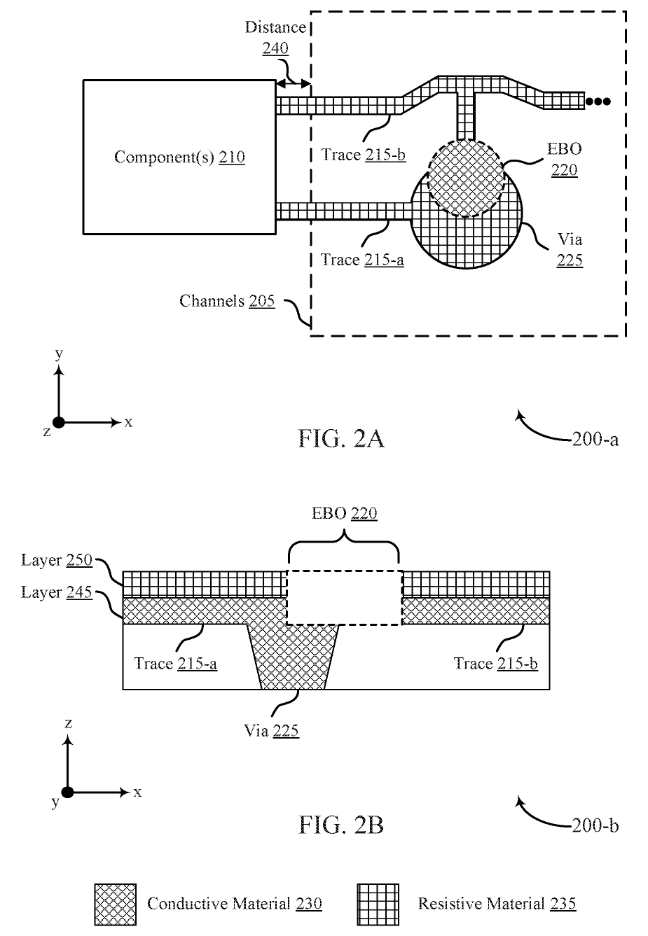

FIGS. 2A and 2B show examples of a semiconductor device 200 that supports unique via structures for semiconductor packages in accordance with examples as disclosed herein. The semiconductor device 200 may implement, or be implemented by, one or more aspects of the system 100. For example, the semiconductor device 200 shows circuitry within a memory system, such as a memory system 110 described with reference to FIG. 1. In some cases, the semiconductor device 200 may support a set of channels 205 being coupled with components 210, where traces 215 (e.g., channel traces, conductive traces, bond fingers) may be isolated from one another based on an EBO 220 formed at a via 225. In some examples, the EBO 220 may support electrically isolating the traces 215 from one another, which may enable the traces 215 to convey signaling to the components 210 without interference from other traces 215. It should be noted that, while the semiconductor device 200 is illustrated and described with reference to two traces 215 (e.g., a trace 215-a and a trace 215-b) and one via 225, the semiconductor device 200 may include any quantity of traces 215 and vias 225.

FIG. 2A illustrates an example of a semiconductor device 200-a, which may be a top-down view of the semiconductor device 200 (e.g., in an xy-plane). The semiconductor device 200-a may include a trace 215-a (e.g., a first trace) and a trace 215-b (e.g., a second trace) that are each electrically connected with a via 225 (e.g., a through silicon via (TSV), a through dielectric via (TDV), or the like) during formation of the semiconductor device 200-a. In some examples, the via 225 may extend through a stack of materials of the semiconductor device 200-a (e.g., towards a substrate of the semiconductor device 200-a, in a z direction) and may couple with one or more features of the semiconductor device 200-a, such as memory cells, access circuitry, or the like. Each of the trace 215-a, the trace 215-b, and the via 225 may include a conductive material 230 (e.g., a copper material) and may be in electrical connection based on the trace 215-a and the trace 215-b physically contacting the via 225. In the example illustrated by the semiconductor device 200-a, a layer of a resistive material 235 may be formed over the trace 215-a, the trace 215-b, and the via 225 (e.g., a top layer of the semiconductor device 200 may be made of the resistive material and a layer directly below the top layer may be made of the conductive material 230). The traces 215 may be oriented according to any configuration, and are not limited to the configuration illustrated by FIG. 2A. For example, the traces 215 may couple with any side of the via 225, may route through the semiconductor device 200-a according to any suitable path, and may include any suitable conductive material.

The traces 215 may be configured to communicate signaling to one or more components 210. For example, the traces 215 (e.g., bond fingers) may extend beyond the channels 205 to couple with the components 210. The components 210 may be components of a memory system, such as memory devices, memory dies, memory controllers, or any combination thereof, among other examples. Additionally, or alternatively, the components 210 may be components external to the memory system, such as components of a host system. In some examples, the electrical connection between the trace 215-a and the trace 215-b may result in interference when communicating signaling.

To electrically isolate the trace 215-a from the trace 215-b, the EBO 220 may be formed at a surface of the via 225. For example, the traces 215 may be formed at a first layer (e.g., a layer 245, as described with reference to FIG. 2B) of the stack of materials of the semiconductor device 200 and a portion of a first surface of the via 225 (e.g., a top surface, a surface of the via 225 at the first layer) may be removed (e.g., etched) to form the EBO 220. In some examples, the EBO 220 may be formed such that a portion of the EBO 220 overlaps with the surface of the via 225 or may be formed such that the entire EBO 220 overlaps with the surface of the via 225. In some examples, to remove the portion of the first surface of the via 225, an etch (or any other suitable removal operation) may be performed according to various techniques, such as a wet etch, a dry etch, or any other suitable material removal technique. In some examples, etching the EBO 220 may remove a plating line after performing metal plating (e.g., copper plating, nickel plating, gold plating) on the semiconductor device 200-a. The EBO 220 may isolate the trace 215-b from the trace 215-a and the via 225, which may support the trace 215-a and the trace 215-b serving as bond fingers to couple with the components 210. In some examples, the trace 215-a may continue to contact a second portion of the first surface of the via 225 after forming the EBO 220. In some examples, similar techniques may be performed to isolate traces at additional vias 225. For example, the semiconductor device 200 may include a third trace 215 and a fourth trace 215 coupled with a second via 225 (not shown), where the fourth trace 215 may be isolated from the third trace 215 and the second via 225 by second EBO 220.

In some examples, forming EBOs 220 over the existing via structure may reduce a distance 240 associated with the bond fingers. For example, the distance 240 may be reduced relative to a system where an EBO is formed at a portion of the semiconductor device 200 between the channels 205 and the components 210. Such a reduced distance may improve flexibility associated with incorporating the semiconductor device 200 into another system or device.

FIG. 2B illustrates an example of a semiconductor device 200-b, which may be a cross-sectional view of the semiconductor device 200-a (e.g., in a xz-plane). For example, the semiconductor device 200-b shows a layer 250 including the resistive material 235 and a layer 245 including the conductive material 230, where traces 215 may be formed at the layer 245 and a first surface (e.g., a top surface) of the via 225 may couple with the traces 215 at the layer 245. In some examples, the semiconductor device 200-a may include the EBO 220 that electrically isolates the trace 215-b from the trace 215-a and the via 225.

As described with reference to FIG. 2A, the EBO 220 may be formed by removing (e.g., etching) a first portion of the first surface of the via 225. For example, removing the first portion of the first surface of the via 225 may include removing (e.g., etching) the resistive material 235 from the layer 250 and removing (e.g., etching) the conductive material 230 from the layer 245. In some cases, removing the resistive material 235 and the conductive material 230 may form a hole corresponding to the EBO 220, where the hole may be within the first surface of the via 225. For example, the trace 215-b may be electrically isolated from the trace 215-a and the via 225 based on a void (e.g., the EBO 220) being formed between the trace 215-b and the via 225. The hole may be formed according to various shapes or sizes within the first surface of the via 225, such as a circular hole, a cylindrical hole, an ovular hole, a spherical hole, a square hole, a hexagonal hole, or any other suitable shape for introducing a void between the trace 215-b and the via 225. The hole may occupy any portion of the first surface of the via 225, for example being formed within a relatively large portion of the first surface of the via 225 (e.g., occupying more than half of the first surface of the via 225) or a relatively small portion of the first surface of the via 225 (e.g., occupying less than half of the first surface of the via 225). In some cases, respective holes formed at different vias 225 of the semiconductor device 200 may be formed according to different shapes, sizes, techniques, or any combination thereof to support isolating traces 215 from vias 225.

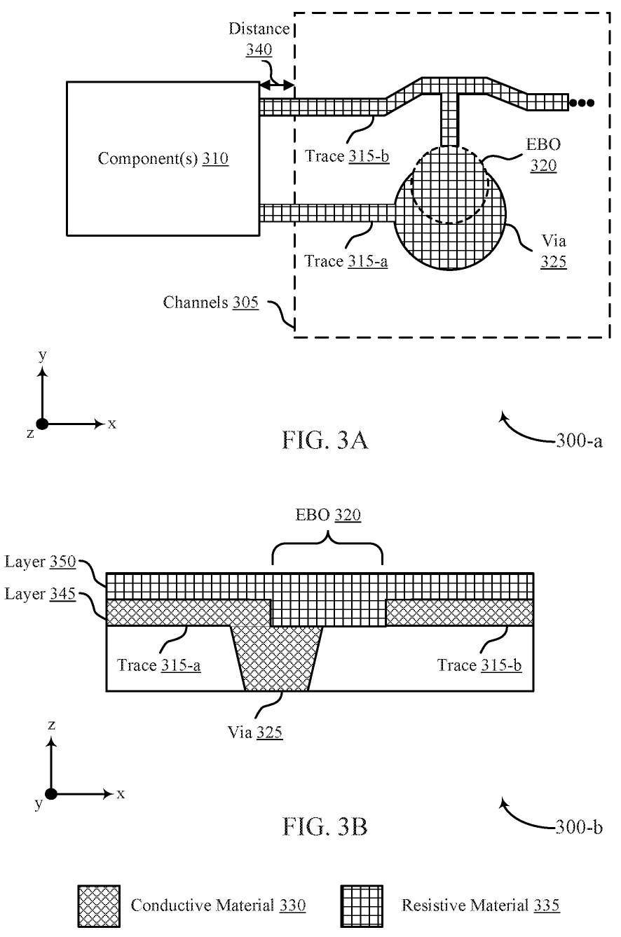

FIGS. 3A and 3B show examples of a semiconductor device 300 that supports unique via structures for semiconductor packages in accordance with examples as disclosed herein. The semiconductor device 300 may implement, or be implemented by, one or more aspects of the system 100 and the semiconductor device 200. For example, the semiconductor device 300 may be an example of the semiconductor device 200 after one or more manufacturing steps. The semiconductor device 300 may include channels 305, one or more components 310, traces 315, an EBO 320, a via 325, a layer 345 of conductive material 330, and a layer 350 of resistive material 335, each of which may be an example of corresponding aspects described with reference to FIGS. 2A and 2B. In some examples, the semiconductor device 300 may support electrically isolating the trace 315-b from the trace 315-a and the via 325 by depositing the resistive material 335 in the EBO 320.

FIG. 3A illustrates a semiconductor device 300-a, which may be an example of a top-down view (e.g., in an xy-plane) of the semiconductor device 300. In some cases, the EBO 320 may be filled with the resistive material 335 (e.g., plugged with solder resist material). For example, after removing material from the semiconductor device 300 (e.g., etching the EBO 320 to form a hole or void, as described with reference to FIGS. 2A and 2B), the resistive material 335 may be added (e.g., deposited) within the hole corresponding to the EBO 320. In some cases, adding the resistive material 335 may result in an electrical disconnection between the trace 315-b and the trace 315-a and the via 325. In some examples, the trace 315-a may remain in electrical connection (e.g., may still physically contact) the via 325 after the resistive material 335 is added. In some other examples, the resistive material 335 may not be added to the semiconductor device 300, and the trace 315-b may be electrically disconnected from the via 325 based on the void (e.g., the hole) between the trace 315-b and the via 325 (e.g., due to a relatively high dielectric constant of air). Additionally, or alternatively, the resistive material 335 may be added (e.g., deposited) such that the resistive material 335 occupies a portion of the hole corresponding to the EBO 320 (e.g., the resistive material 335 may not occupy the entire EBO 320).

FIG. 3B illustrates a semiconductor device 300-b, which may be an example of a cross-sectional view (e.g., in an xz-plane) of the semiconductor device 300-a. As illustrated by the semiconductor device 300-b, the EBO 320 may be filled with the resistive material 335 such that a top surface of the semiconductor device 300 (e.g., a surface of the layer 350) is smooth and continuous. By adding (e.g., depositing) the resistive material 335 into the EBO 320, the trace 315-b may be isolated from the via 325 and the trace 315-a. Such techniques may enable the trace 315-a and the trace 315-b to serve as functional signal traces at the layer 345. By forming the EBO 320 at a surface of the via 325, a footprint of the semiconductor device 300 (e.g., dimensions in the xy-plane) may be reduced relative to a system where an EBO is formed between the channels 305 and the components 310. In some cases, the resistive material 335 may be the same material as the material used to form the layer 350 or may be a different resistive material than the material used to form the layer 350.

In some examples, forming EBOs 320 over the existing via structure may reduce a distance 340 associated with the bond fingers. For example, the distance 340 may be reduced relative to a system where an EBO is formed at a portion of the semiconductor device 300 between the channels 305 and the components 310. Such a reduced distance may improve flexibility associated with incorporating the semiconductor device 300 into another system or device.

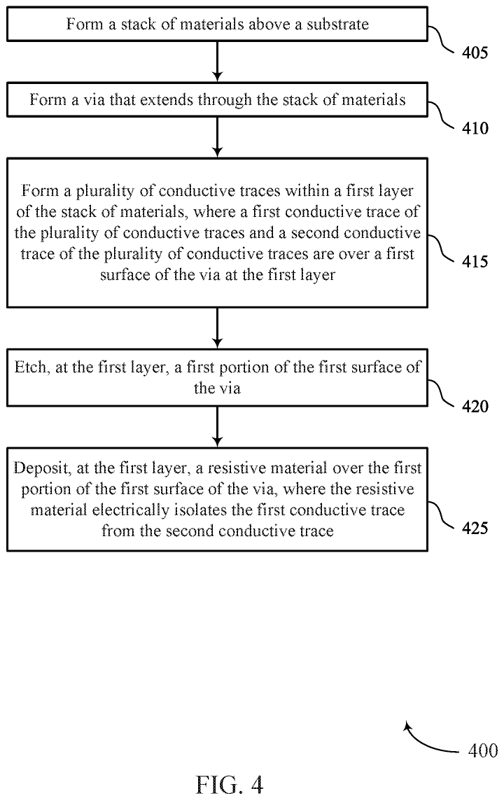

FIG. 4 shows a flowchart illustrating a method 400 that supports unique via structures for semiconductor packages in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a stack of materials above a substrate.

At 410, the method may include forming a via that extends through the stack of materials.

At 415, the method may include forming a plurality of conductive traces within a first layer of the stack of materials, where a first conductive trace of the plurality of conductive traces and a second conductive trace of the plurality of conductive traces are over a first surface of the via at the first layer.

At 420, the method may include removing (e.g., etching), at the first layer, a first portion of the first surface of the via.

At 425, the method may include adding (e.g., depositing), at the first layer, a resistive material over the first portion of the first surface of the via, where the resistive material electrically isolates the first conductive trace from the second conductive trace.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a stack of materials above a substrate; forming a via that extends through the stack of materials; forming a plurality of conductive traces within a first layer of the stack of materials, where a first conductive trace of the plurality of conductive traces and a second conductive trace of the plurality of conductive traces are over a first surface of the via at the first layer; removing, at the first layer, a first portion of the first surface of the via; and adding, at the first layer, a resistive material over the first portion of the first surface of the via, where the resistive material electrically isolates the first conductive trace from the second conductive trace.

Aspect 2: The method or apparatus of aspect 1, where removing the first portion of the first surface of the via includes operations, features, circuitry, logic, means, or instructions, or any combination thereof for removing the resistive material from a second layer of the stack of materials above the first layer and removing a conductive material from the first portion of the first surface of the via.

Aspect 3: The method or apparatus of any of aspects 1 through 2, where removing the first portion of the first surface of the via includes operations, features, circuitry, logic, means, or instructions, or any combination thereof for removing a conductive material from the first surface of the via to form a hole corresponding to an etchback opening, where the hole is within the first surface of the via.

Aspect 4: The method or apparatus of any of aspects 1 through 3, further including operations, features, circuitry, logic, means, or instructions, or any combination thereof for forming a second via that extends through the stack of materials, where a third conductive trace of the plurality of conductive traces and a fourth conductive trace of the plurality of conductive traces are over a first surface of the second via at the first layer; removing, at the first layer, a first portion of the first surface of the second via; and adding, at the first layer, the resistive material over the first portion of the first surface of the via, where the resistive material electrically isolates the third conductive trace from the fourth conductive trace.

Aspect 5: The method or apparatus of any of aspects 1 through 4, further including operations, features, circuitry, logic, means, or instructions, or any combination thereof for coupling the first conductive trace and the second conductive trace with one or more components of the semiconductor device, where the first conductive trace and the second conductive trace are configured to convey signaling to the one or more components based at least in part on coupling the first conductive trace and the second conductive trace with the one or more components.

Aspect 6: The method or apparatus of aspect 5, where the one or more components include one or more memory dies of the semiconductor device, one or more controllers of the semiconductor device, or any combination thereof.

Aspect 7: The method or apparatus of any of aspects 1 through 6, where the first conductive trace, the second conductive trace, and the via each include a conductive material.

Aspect 8: The method or apparatus of aspect 7, where the conductive material includes a copper material.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A semiconductor device, including: a stack of materials formed over a substrate; a via extending through the stack of materials; a first conductive trace over a first portion of a first surface of the via; and a resistive material over a second portion of the first surface of the via, where the resistive material electrically isolates the first conductive trace from a second conductive trace of the semiconductor device.

Aspect 10: The semiconductor device of aspect 9, where the resistive material electrically isolates the second conductive trace from the via.

Aspect 11: The semiconductor device of any of aspects 9 through 10, further including: one or more components coupled with the first conductive trace and the second conductive trace, where the first conductive trace and the second conductive trace are configured to convey signaling to the one or more components.

Aspect 12: The semiconductor device of aspect 11, where the one or more components include one or more memory dies of the semiconductor device, one or more controllers of the semiconductor device, or any combination thereof.

Aspect 13: The semiconductor device of any of aspects 9 through 12, where the first conductive trace, the second conductive trace, and the via each include a conductive material.

Aspect 14: The semiconductor device of aspect 13, where the conductive material includes a copper material.

Aspect 15: The semiconductor device of any of aspects 9 through 14, where the resistive material is over the second portion of the first surface of the via based at least in part on the resistive material being located within an etchback opening formed above the second portion of the first surface of the via.

Aspect 16: The semiconductor device of any of aspects 9 through 15, where: the first conductive trace is in contact with the first portion of the first surface of the via; the resistive material is in contact with the second portion of the first surface of the via; a first surface of the first conductive trace is in contact with the resistive material; a second surface of the second conductive trace is in contact with the resistive material; and a portion of the resistive material is over each of the first conductive trace and the second conductive trace.

Aspect 17: The semiconductor device of any of aspects 9 through 16, further including: a second via extending through the stack of materials; a third conductive trace over a first portion of a first surface of the second via extending through the stack of materials; and the resistive material over a second portion of the first surface of the second via extending through the stack of materials, where the resistive material electrically isolates the third conductive trace from a fourth conductive trace of the semiconductor device.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a stack of materials formed over a substrate;
a via extending through the stack of materials;
a first conductive trace over a first portion of a first surface of the via; and
a resistive material over a second portion of the first surface of the via, wherein the resistive material electrically isolates the first conductive trace from a second conductive trace of the semiconductor device.

2. The semiconductor device of claim 1, wherein the resistive material electrically isolates the second conductive trace from the via.

3. The semiconductor device of claim 1, further comprising:
one or more components coupled with the first conductive trace and the second conductive trace, wherein the first conductive trace and the second conductive trace are configured to convey signaling to the one or more components.

4. The semiconductor device of claim 3, wherein the one or more components comprise one or more memory dies of the semiconductor device, one or more controllers of the semiconductor device, or any combination thereof.

5. The semiconductor device of claim 1, wherein the first conductive trace, the second conductive trace, and the via each comprise a conductive material.

6. The semiconductor device of claim 5, wherein the conductive material comprises a copper material.

7. The semiconductor device of claim 1, wherein the resistive material is over the second portion of the first surface of the via based at least in part on the resistive material being located within an etchback opening formed above the second portion of the first surface of the via.

8. The semiconductor device of claim 1, wherein:
the first conductive trace is in contact with the first portion of the first surface of the via;
the resistive material is in contact with the second portion of the first surface of the via;
a first surface of the first conductive trace is in contact with the resistive material;
a second surface of the second conductive trace is in contact with the resistive material; and
a portion of the resistive material is over each of the first conductive trace and the second conductive trace.

9. The semiconductor device of claim 1, further comprising:
a second via extending through the stack of materials;
a third conductive trace over a first portion of a first surface of the second via extending through the stack of materials; and
the resistive material over a second portion of the first surface of the second via extending through the stack of materials, wherein the resistive material electrically isolates the third conductive trace from a fourth conductive trace of the semiconductor device.

10. A method of forming a semiconductor device, comprising:
forming a stack of materials above a substrate;
forming a via that extends through the stack of materials;
forming a plurality of conductive traces within a first layer of the stack of materials, wherein a first conductive trace of the plurality of conductive traces and a second conductive trace of the plurality of conductive traces are over a first surface of the via at the first layer;
removing, at the first layer, a first portion of the first surface of the via; and
adding, at the first layer, a resistive material over the first portion of the first surface of the via, wherein the resistive material electrically isolates the first conductive trace from the second conductive trace.

11. The method of claim 10, wherein removing the first portion of the first surface of the via comprises:
removing the resistive material from a second layer of the stack of materials above the first layer; and
removing a conductive material from the first portion of the first surface of the via.

12. The method of claim 10, wherein removing the first portion of the first surface of the via comprises:
removing a conductive material from the first surface of the via to form a hole corresponding to an etchback opening, wherein the hole is within the first surface of the via.

13. The method of claim 10, further comprising:
forming a second via that extends through the stack of materials, wherein a third conductive trace of the plurality of conductive traces and a fourth conductive trace of the plurality of conductive traces are over a first surface of the second via at the first layer;
removing, at the first layer, a first portion of the first surface of the second via; and
adding, at the first layer, the resistive material over the first portion of the first surface of the via, wherein the resistive material electrically isolates the third conductive trace from the fourth conductive trace.

14. The method of claim 10, further comprising:
coupling the first conductive trace and the second conductive trace with one or more components of the semiconductor device, wherein the first conductive trace and the second conductive trace are configured to convey signaling to the one or more components based at least in part on coupling the first conductive trace and the second conductive trace with the one or more components.

15. The method of claim 14, wherein the one or more components comprise one or more memory dies of the semiconductor device, one or more controllers of the semiconductor device, or any combination thereof.

16. The method of claim 10, wherein the first conductive trace, the second conductive trace, and the via each comprise a conductive material.

17. The method of claim 16, wherein the conductive material comprises a copper material.

18. A semiconductor device formed by a process comprising:
forming a stack of materials above a substrate;
forming a via that extends through the stack of materials;
forming a plurality of conductive traces within a first layer of the stack of materials, wherein a first conductive trace of the plurality of conductive traces and a second conductive trace of the plurality of conductive traces are over a first surface of the via at the first layer;
removing, at the first layer, a first portion of the first surface of the via; and
adding, at the first layer, a resistive material over the first portion of the first surface of the via, wherein the resistive material electrically isolates the first conductive trace from the second conductive trace.

19. The semiconductor device of claim 18, wherein the process of removing the first portion of the first surface of the via comprises:
removing the resistive material from a second layer of the stack of materials above the first layer; and
removing a conductive material from the first portion of the first surface of the via.

20. The semiconductor device of claim 18, wherein the process of removing the first portion of the first surface of the via comprises:
removing a conductive material from the first surface of the via to form a hole corresponding to an etchback opening, wherein the hole is within the first surface of the via.

21. The semiconductor device of claim 18, wherein the process further comprises:
forming a second via that extends through the stack of materials, wherein a third conductive trace of the plurality of conductive traces and a fourth conductive trace of the plurality of conductive traces are over a first surface of the second via at the first layer;
removing, at the first layer, a first portion of the first surface of the second via; and
adding, at the first layer, the resistive material over the first portion of the first surface of the via, wherein the resistive material electrically isolates the third conductive trace from the fourth conductive trace.

22. The semiconductor device of claim 18, wherein the process further comprises:
coupling the first conductive trace and the second conductive trace with one or more components of the semiconductor device, wherein the first conductive trace and the second conductive trace are configured to convey signaling to the one or more components based at least in part on coupling the first conductive trace and the second conductive trace with the one or more components.

23. The semiconductor device of claim 22, wherein the one or more components comprise one or more memory dies of the semiconductor device, one or more controllers of the semiconductor device, or any combination thereof.

24. The semiconductor device of claim 18, wherein the first conductive trace, the second conductive trace, and the via each comprise a conductive material.

25. The semiconductor device of claim 24, wherein the conductive material comprises a copper material.
